(19) United States
(12) Patent Application Publication
(10) Pub. No.: US 2006/0175190 A1
(43) Pub. Date: Aug. 10, 2006

(54) Vacuum arc source comprising a device for generating a magnetic field

(75) Inventors: Andreas Schuetze, Feldkirch (AT); Christian Wohlrab, Feldkirch (AT)

Correspondence Address: PEARNE & GORDON LLP, 1801 EAST 9TH STREET, SUITE 1200, CLEVELAND, OH, 44114-3108, US

(73) Assignee: Unaxis Balzers Ltd., Balzers (LI)

(21) Appl. No.: 10/540,162

(22) PCT Filed: Oct. 30, 2003
(86) PCT No.: PCT/CH03/00710

§ 371 Date: Dec. 23, 2005

(30) Foreign Application Priority Data
Dec. 19, 2002 (CH) 2163/02

(51) Int. Cl. C23C 14/32; C23C 14/00

(52) U.S. Cl. 204/192.38; 204/298.41

(57) ABSTRACT

The invention relates to a vacuum arc source and to a method for operating the same, said source comprising a target with a surface for operating an arc discharge. The target is arranged in the range of influence of a device for generating a magnetic field, said device comprising at least two magnetic systems of opposite polarity and being embodied in such a way that the component B_{⊥} which is perpendicular to the surface and pertains to the resulting magnetic field has essentially constantly low values over a large part of the surface or has a value equal to zero.

This invention concerns a vacuum arc source for operating an arc discharge according to claim 1, a system outfitted with such an arc source in claim 17, and a method of operating an arc discharge in claim 21.

Arc sources, as they are known in a vacuum chamber for vaporizing different materials and/or as ion sources, are used for coating and pre-treating different workpieces. Because of the high built-in energy pointing at the target surface of the arc, hereinafter called a spark, moving on the target surface of the arc source, besides the emission of gaseous, for the most part ionized particles, especially with spark “burnout” and the resultant explosive-type vaporization, there are also emissions of macroparticles, whose diameter can run up to several micrometers or more. After coating, the surface roughness of previously polished workpieces, for example, is basically determined by the number and size of the macroparticles adhering to the surface of the layer or grown into it. Therefore, layers deposited in this way are relatively rough, which has a negative effect when a coated tool or component is used. Furthermore, a large number of macroparticles leave the surface of the target at a relatively flat angle, and valuable material is lost in coating processes and deposited on the inside of the vacuum chamber.

Different solutions have been proposed for depositing smoother layers. For example, arc sources were placed outside the optical line of sight of the workpiece and ionized particles were guided in the direction of the workpieces by means of magnetic fields, whereby smoother layers were achieved at high technical expense, but the coating rate basically decreased at the same time.

Different arc sources have also been developed to move the spark as quickly as possible on a defined path over the target surface and to prevent too much energy from getting onto a small surface or even “burnout.” The spark was therefore forced onto a closed circuit by one or more magnets moved behind the target, for example.

Another way of controlling the spark is described in U.S. Pat. No. 5,298,136. This document is regarded as the most recent state of the art. An arc source disclosed there has a circular target, which is surrounded laterally from the back by a cup-shaped pole shoe with a central pole piece on the back of the target and a coil in between. This produces a magnetic field over the target, whose vertical component has a positive maximum in the middle of the target, falls symmetrically to smaller values to a negative minimum on the rim and then rises asymptotically in the direction of the abscissa. Similar magnetic fields can also be produced by placing permanent magnets on the back of the target, as known. Here the zero passage of the field lines going through the abscissa (i.e. zero passage corresponds to a change in field direction) on the target surface is a closed (circular) line on which the perpendicular component of the magnetic field is zero.

On this zero line, the spark entering the target from the plasma, with a target connected via the cathode for example, in the technical direction of the current, experiences not radial, but high tangential acceleration, since the parallel component of the magnetic field has a maximum on the same line. The high rotational speed of the spark achieved in this way effectively prevents “seizing,”but at the same time causes poor target utilization, since basically only a narrow circular ring of the target is removed.

To improve this, a solenoid coil surrounding the target and the pole shoe was also provided in the upper area, with which the radius of the zero line produced by the pole shoe and the coil placed in it can be moved radially.

However, the technical expense necessary for this is relatively high, since an independent current/voltage control unit is provided for both coils, whereby at least one of them must be suited for giving off time-altered current/voltage signals, in order to make periodic expansion/contraction of the zero line possible on the target. In any case, despite the high expense, on this type of arc source, a relatively large area in the middle of the target is removed very little or not at all.

The problem of this invention is to remove the disadvantages in the state of the art that have been mentioned.

The problem is especially to make a vacuum arc source and a method of operating an arc discharge that allows generally improved, more economical treatment processes with higher layer quality compared to the source or sources used conventionally or compared to the conventional methods. This involves the following points in particular:
improving target utilization
lengthening target tool time
increasing the coating processes that can be achieved per target
reducing process times
reducing the surface roughness of the layers deposited.

To solve this problem, the invention proposes a vacuum arc source in claim 1, a vacuum system in claim 17 and a procedure according to the method in claim 21.

Surprisingly, it has been shown that when a magnetic field is set to the surface of a target whose perpendicular component B⊥ runs over a large part of the surface basically constantly near or at zero, a spark path is made possible in which the spark runs quickly and evenly over the entire target surface or at least the greater part of it. This way, on one hand, the spark area melted by individual sparks per unit of time on the target surface remains small, and the size and number of macroparticles emitted from the molten bath is reduced. On the other hand, a better yield can be achieved with it than with a spark forced to run over a relatively small area of the target.

Advantageously, the magnetic field component B⊥ chosen is smaller than 30, preferably smaller than 20, and highly preferably smaller than 10 Gauss. On the rim of the target surface, the values B⊥_{R} of the perpendicular magnetic field component can be set to rise, fall and/or change signs in the middle of the target surface.

The greater part of the surface, i.e., the area in which the perpendicular component B⊥ runs basically constantly near or at zero, extends advantageously from the middle of the target surface up to the rim and includes at least 50%, but preferably at least 60% of the geometrically determining mass or masses. In the case of a square target, for example, at least 50% or 60% of sides a, b, in the case of a circular target, at least 50% or 60% of the radius. On the rim of the target surface, the values B⊥_{R} of the perpendicular magnetic field component can be set to rise, fall and/or change signs compared to the values B⊥ in the middle of the target surface.

The value of the parallel magnetic field component B_{∥} can also basically be set at zero in the middle, in the direction of the rim of the target surface but rise, preferably rise symmetrically toward the middle of the target. For example, if a magnetic field with an approximately linearly rising component B_{∥} is applied to circular targets from the rim to near the middle, the force acting on the spark tangentially clockwise or counterclockwise toward the rim of the target rises, whereby the spark can run over the radius at an approximately constant angular speed.

Such a magnetic field can be produced with a vacuum arc source with a device for producing a magnetic field that includes at least two magnet systems with opposite poles.

The following embodiments describe, by way of example, various vacuum arc sources with which such a magnetic field can be produced over the target surface.

As the first of the at least two oppositely poled magnet systems, a first electromagnetic coil can be provided, which can in turn be made up of several coils. Advantageously, the inner dimensions of the first coil basically coincide with a deviation of a maximum of plus/minus 30%, preferably plus/minus 20% with the projection of the outer dimensions of the surface of the target. When a voltage is applied from the coil, which then has current flowing through it, a homogeneous magnetic field is produced running basically perpendicular to the surface of the target. The small parallel component of the magnetic field on the greater part of the surface in relation to the perpendicular component is zero in the middle of the surface and rises toward the rim. It is possible, but not very practical to use an even larger first coil; when smaller diameters are used, the parallel portion is too large, or there is even an unwanted change in field direction. Such fields can be produced with solenoid, i.e., source-free coils, without additional pole shoes or magnetic cores. The portion of the parallel component of the magnetic field increases or decreases depending on the distance to the target surface and the diameter of the coil.

Another way of making the first magnet system can consist of one or more permanent magnets placed behind the target, or behind a cooling plate attached to the back of the target. The magnetic fields produced on the target surface should correspond roughly to one field of a solenoid coil, as described above, i.e., be relatively small. Therefore, the permanent magnets should either have low field strength themselves or be spaced accordingly from the target. Care should also be taken that here again, as in the use of a coil as described above, no reversal of field direction on the target surface is brought about by the first magnet system. An arrangement known from the state of the art with alternating poles between the middle and the rim areas must also be avoided. One simple possibility offered here is to use thin, so-called plastoferrite magnets, which, depending on the field strength to be set, can be placed in the form of single or multilayer disks or polygons on the back of the target as uniformly as possible, as above, into an area of plus/minus 30%, preferably plus/mnuus 20% of the outer dimensions of the surface of the target.

Advantageously, at least one coil including the first magnet system and arranged coaxially to it is provided as the second magnet system. It can, for example, be arranged laterally including the first magnet system or taraget or preferably be placed behind the first magnet system or target.

It is also advantageous for a second coil placed behind the first magnet system to have a larger diameter than that of the first magnet system or the first coil. Likewise, a larger number of windings has proven effective, since that makes it easier to set the perpendicular magnetic field basically at zero in connection with the working of the first magnet system on the surface. With the same number of windings, this effect must be set by a basically higher current flow, whereby there can be a thermal overload of the second coil. In addition, with such a second, in this case more powerful coil, a second magnet system oriented against the effect of the first magnet system can produce a magnetic field that works in the vacuum chamber and allows the otherwise diffuse arc plasma to be bundled into a plasma beam, also called a plasma jet. Here, the opposite parallel components of the two magnet systems, depending on their distance from the target, cancel each other out in part or in full, which causes the bundling, while the more powerful perpendicular field of the second magnet system is canceled out only in the direct area of the target surface by the weaker first magnet system. This is an advantage since a stream of particles directed at the workpiece being treated can be produced, which, for example, allows higher etching rates or faster layer growth and because the process time that can be achieved is shortened, lengthens the general tool life of the target.

Placing the first and second magnet systems behind the target also has the advantage that both magnet systems can be mounted so they are accessible from the outside and not exposed to high temperatures and potential coating in the treatment chamber.

A comparable effect can also be achieved with a coil placed some a distance in front of the target. If a coil is also used as the first magnet system, the second coil can now be made similarly or even the same. With such a more or less symmetrical arrangement of the spools opposite the target plane, the magnetic field of the second must not necessarily larger than that of the first coil to produce a plasma jet, whereby both coils can be operated with similar geometries and with a common current/voltage source. The magnetic field can be fine-tuned simply with adjustable resistors or by adjustable spacing at least of one coil. Since, in this case, the second magnet system is exposed to the stream of particles from the arc source, additional protective measures like cooling or removable protective clothing or other known measures must be provided to guarantee constant operation.

If at least one coil is used for both the first and for the second magnet system, the voltage source or sources must be applied, as is easy to follow from the explanations given above, so that the coil currents flow in opposite directions, i.e., basically clockwise or counter-clockwise.

As described above, devices producing magnetic fields are suitable for use with arc sources that operate with both cathodes and anodes, especially flat ones, and can easily be set for different target materials and/or target thicknesses, when at least one coil is used, for example by changing the coil current, but also by changing the distance of at least one magnet system from the target surface. The target geometry can be adjusted to the respective need, and corresponding devices for producing magnetic fields can be made according to the invention, for example for both round and square or polygonal sources.

It is therefore not necessary to change the coil current or currents during an etching or coating process, although it is possible in principle. The spark or sparks also run in a random pattern similar to so-called “random arc” sources over the target surface, but are directed or accelerated by the magnetic fields of the arc source made according to the invention, so that the sparks are distributed more finely and the spatter frequency is much reduced. Astonishingly, no seizing of the spark can be found in the middle of the target, where both perpendicular and parallel magnetic field components are very small or zero.

Due to the directional effect that can be achieved by the arc source in the invention, the plasma beam produced can also be controlled advantageously by a magnetic field produced in the chamber of the vacuum treatment system. For example, if one or more arc sources is arranged in the direction of the axis of a vacuum treatment system and at the same time at least one other electromagnetic coil placed concentrically to the axis of the system is provided, then the plasma beam produced by the arc source can be deflected. If at least one other coil is connected to a time-altered current source with a control unit, the plasma beam can be directed variably at different areas in the chamber. For example, the plasma beam can be directed past the workpieces for etching processes or preferably periodically over the workpieces for coating processes.

Here it has proven advantageous, at least with a symmetrical arrangement of several sources around a system axis, to choose a coil arrangement with which the most uniform possible axis-parallel field can be produced in the chamber. This is achieved, for example, by a system with at least two other electromagnetic coils, in which the other coils are preferably arranged in the upper and lower or corresponding lateral border areas of the system concentric to the axis of the system. The coils can then have a different diameter or basically the same diameter, corresponding to a Helmholz coil arrangement.

The invention will now be explained using schematic figures, by way of example.

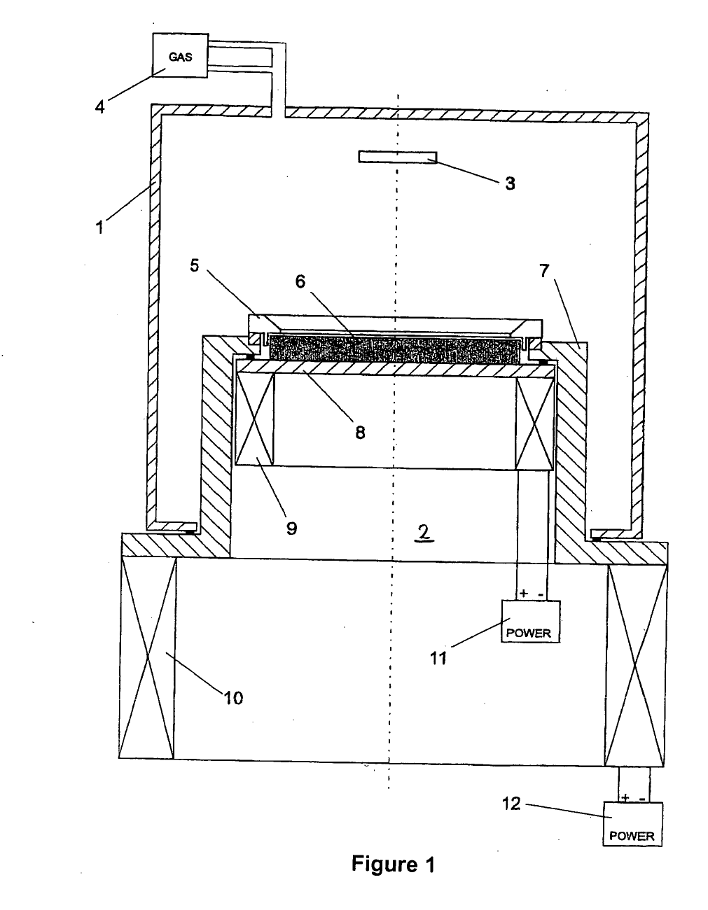

FIG. 1 Arc source with two magnetic systems

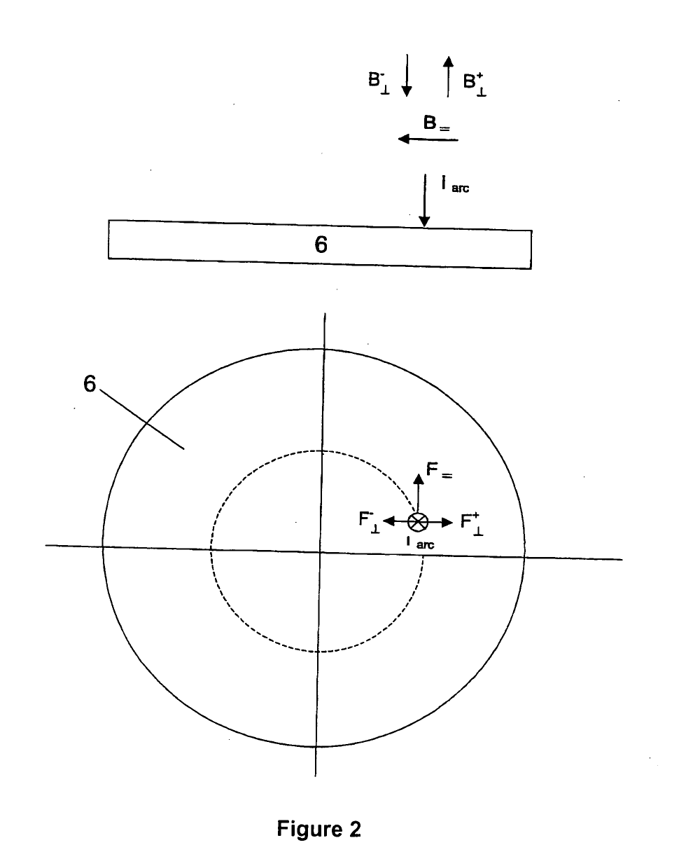

FIG. 2 Spark path on target surface

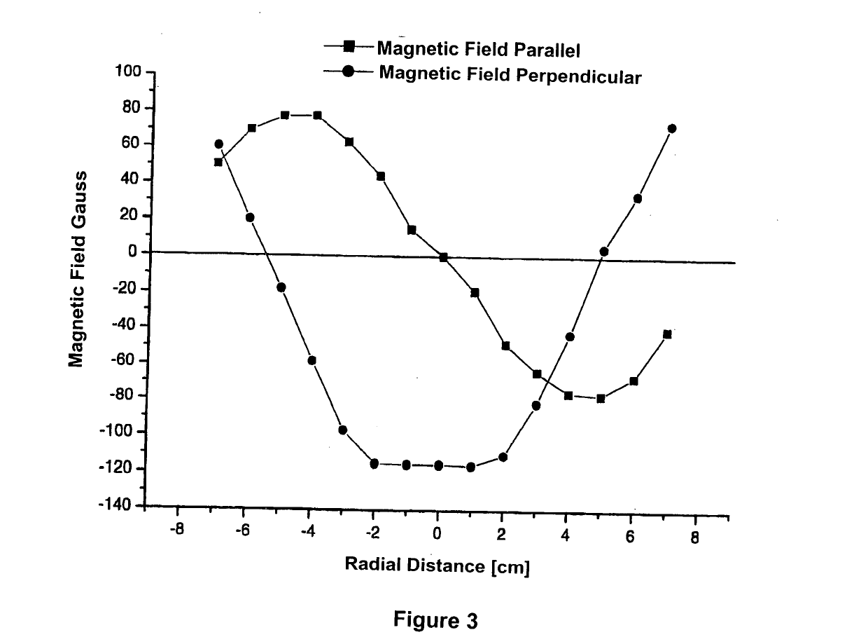

FIG. 3 Path of the magnetic field components in the state of the art

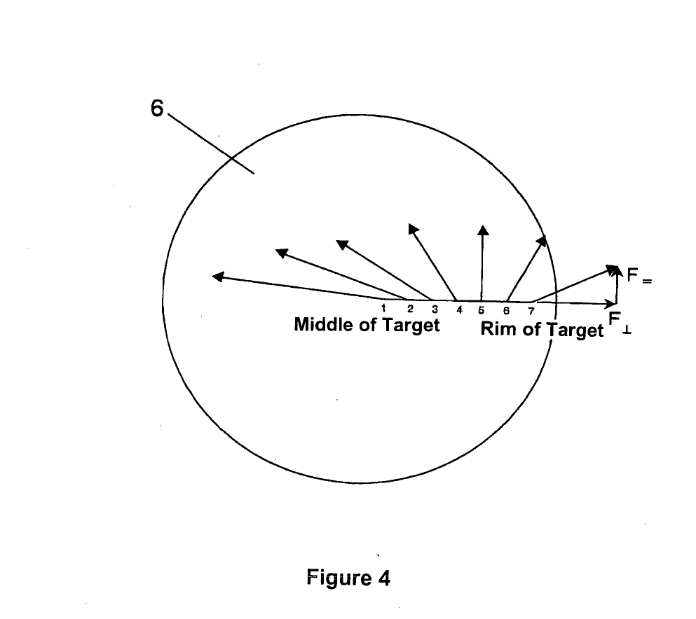

FIG. 4 Magnetic field vectors in FIG. 3

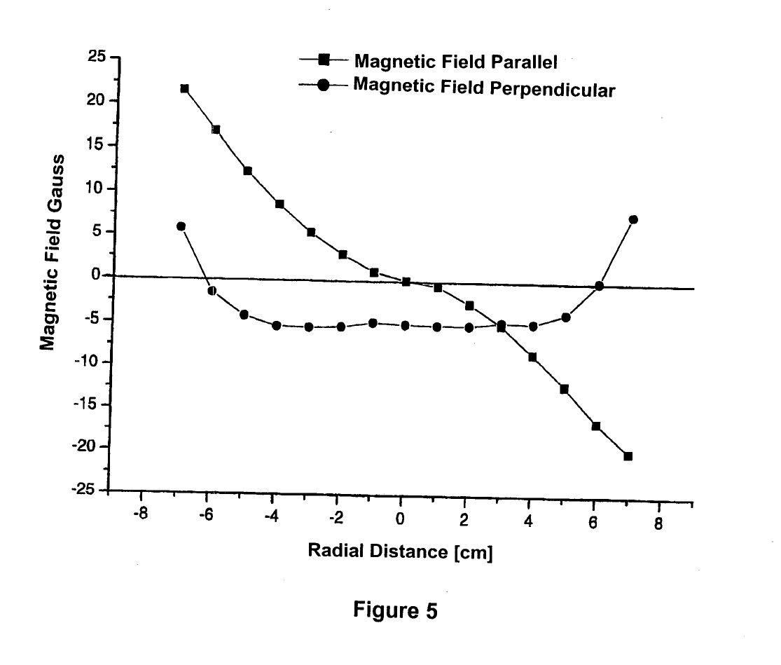

FIG. 5 Path of magnetic field components of the arc source in the invention

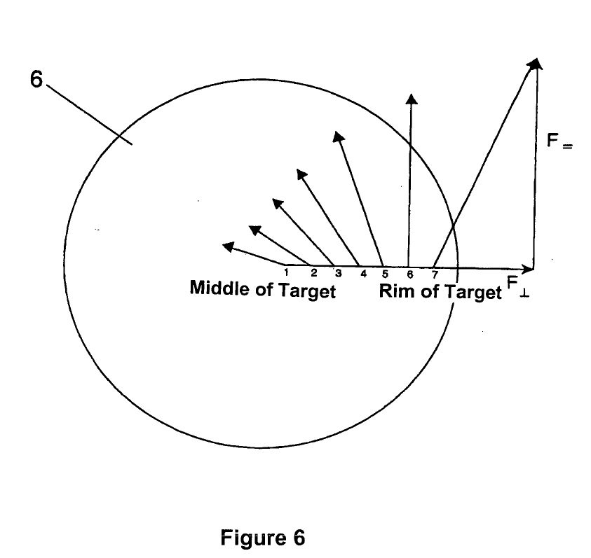

FIG. 6 Magnetic field vectors in FIG. 5

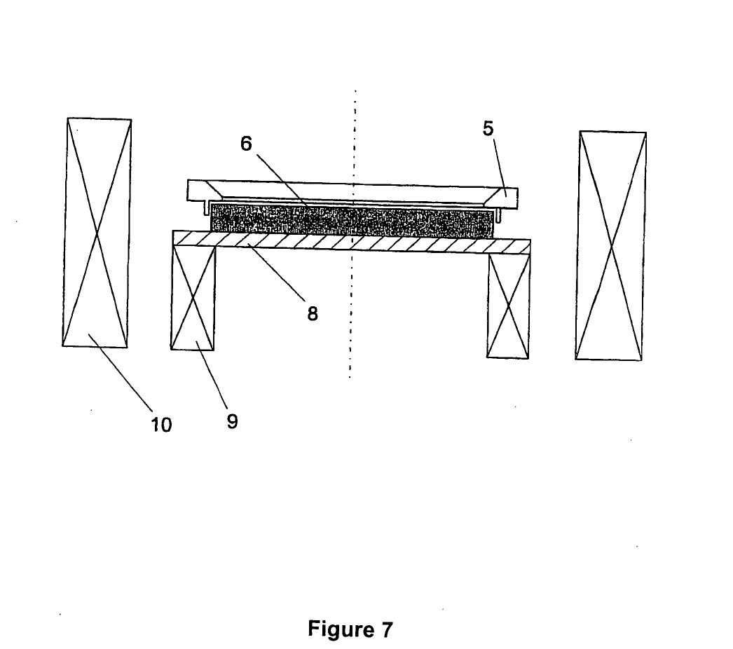

FIG. 7 Arc source with surrounding coil

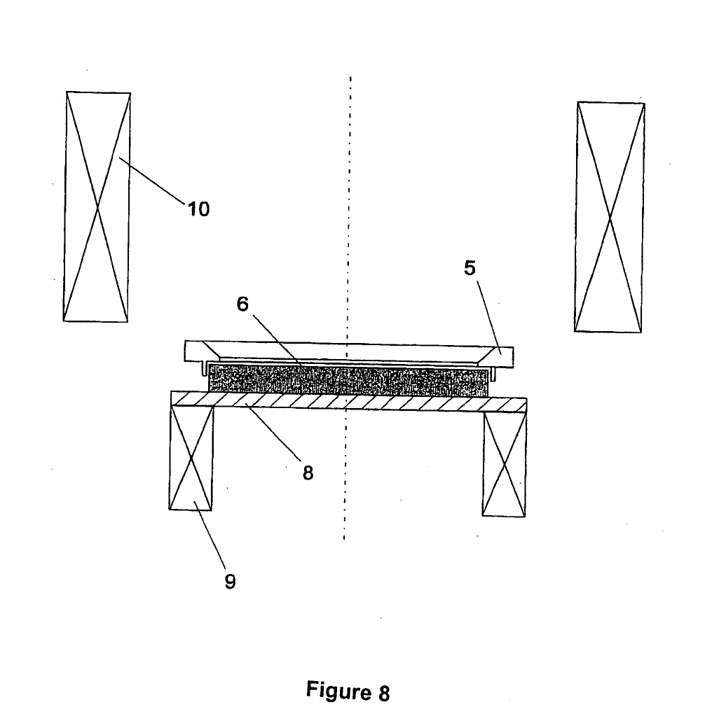

FIG. 8 Arc source with coil in front of target

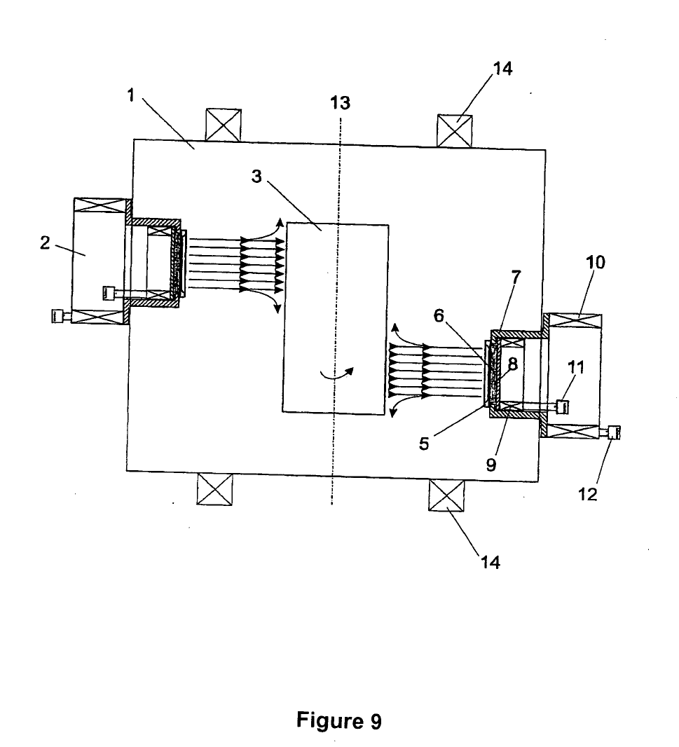

FIG. 9 Section through coating system

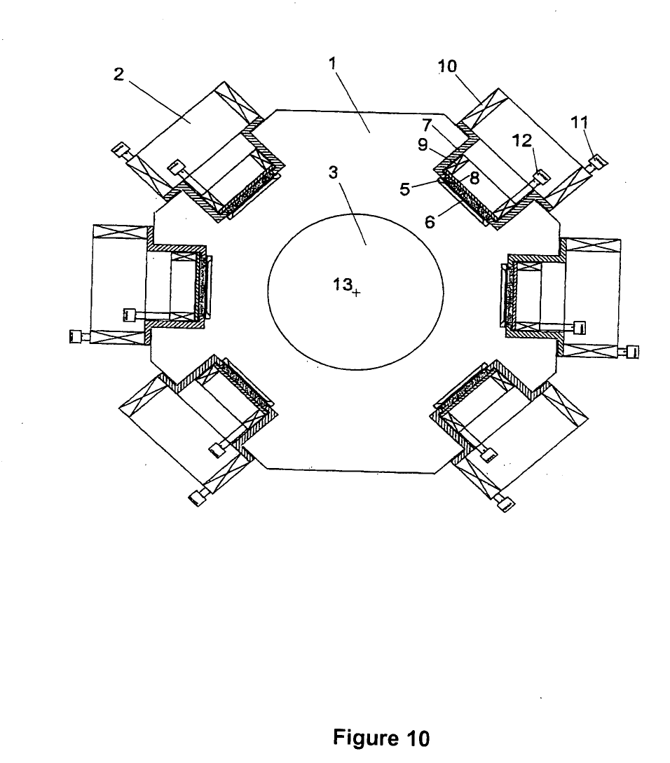

FIG. 10 Cross section of coating system with 6 sources

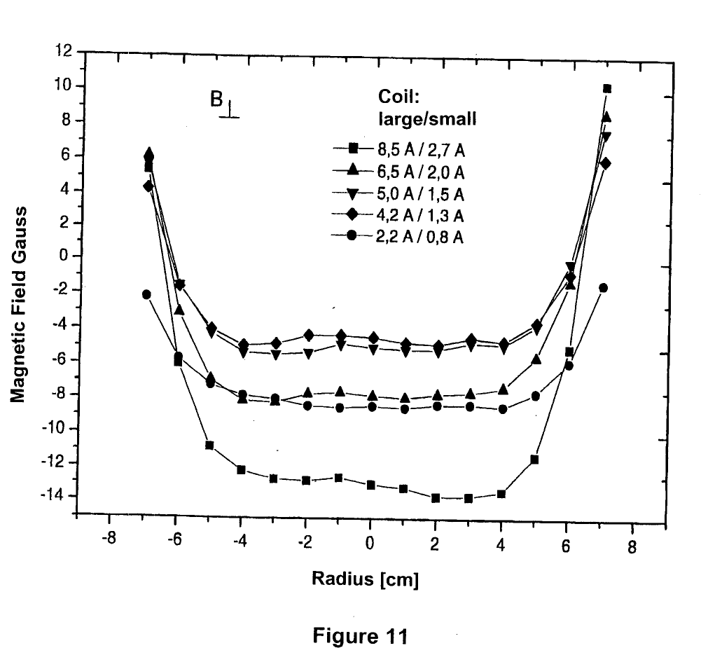

FIG. 11 B⊥ path for optimal operation

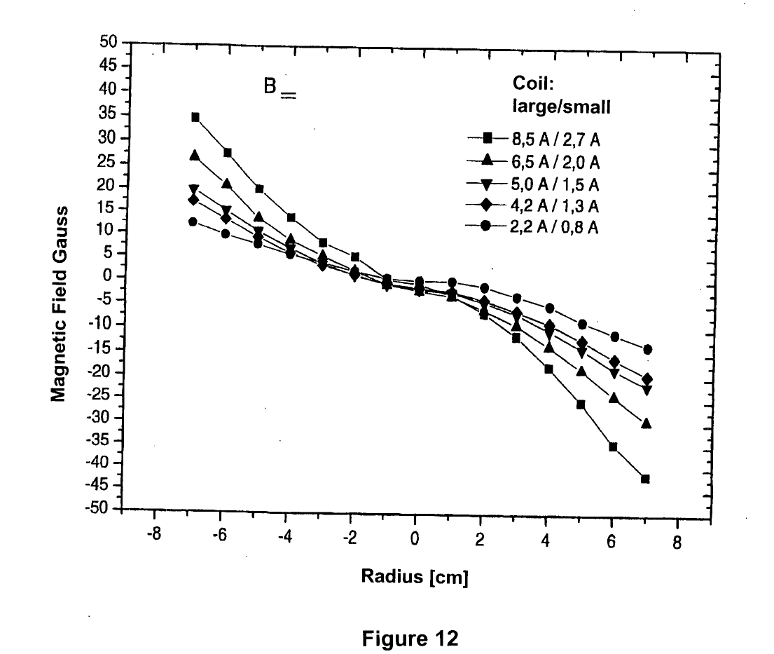

FIG. 12 B_{∥} path for optimal operation

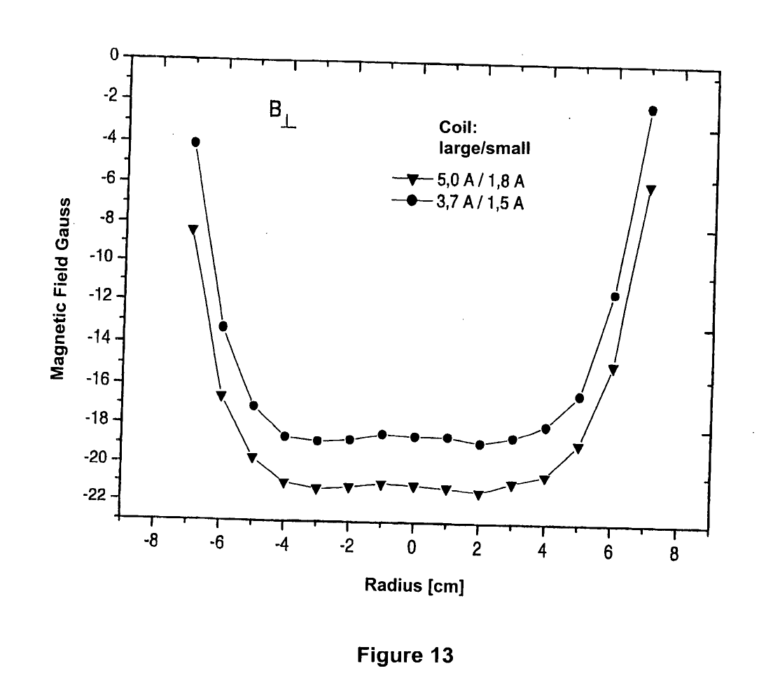

FIG. 13 B⊥ path for spark in middle

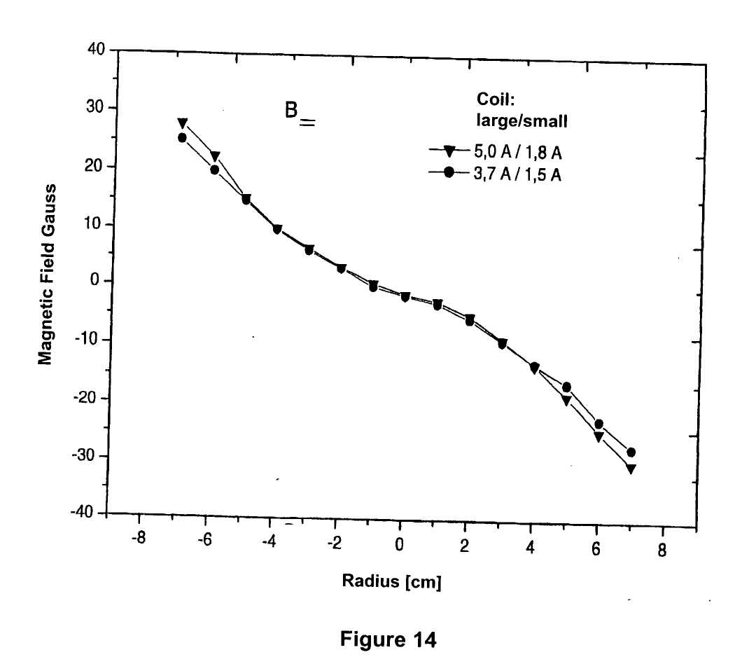

FIG. 14 B_{∥}path for spark in middle

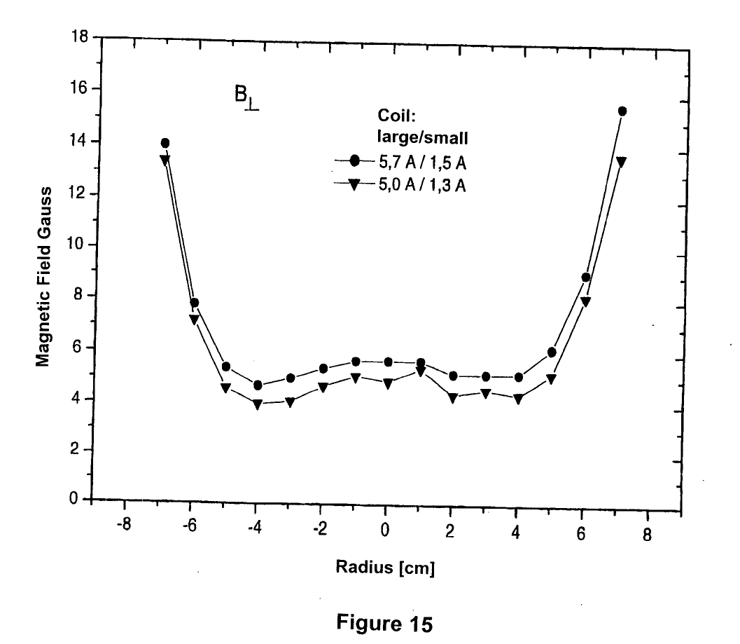

FIG. 15 B⊥ path for spark on rim

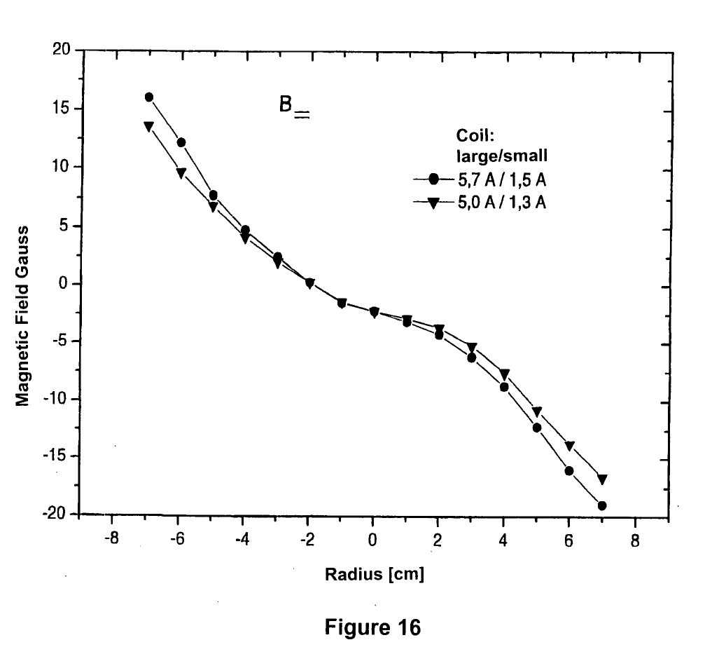

FIG. 16 B_{∥} path for spark on rim

FIG. 1 shows the arc source 2 in the invention built into the chamber of a vacuum treatment system 1 with a gas power supply 4 and various power supply and pump units, not shown here in greater detail, with the arc source 2 working on a workpiece 3. In the embodiment shown, both magnet systems 9, 1 0 are designed in the form of electromagnetic coils and are placed behind the target 6, in or on a source feed 7 that is connected to a target back plate 8 sealing the system to the atmosphere. The first coil assigned to the first magnet system 9 is directly behind the target 6 or behind a target back plate 8 that is water-cooled in a way that is known. The second coil assigned to the second magnet system 10 is also placed behind the target 6, but has a larger inner and outer diameter than the first coil 9. The distance between the first coil 9 and the second coil 10 was set between 0 and 200 mm, in some embodiments at 67 mm. Both coils are outside the chamber, are easily accessible and can, if necessary, be cooled easily. To power the coils, in this case, two independent DC power supplies 11, 12 are provided that supply the DC current required for the respective process or for the respective target.

As targets, circular blanks, for example, with a diameter of 160 mm and a thickness of 6 mm can be made of different materials like Ti or TiAl, for example. Larger and smaller target thicknesses and other shapes are possible, as is known to a person skilled in the art. The coil geometry and a sample setting of the coil currents can be seen in Table 1. To achieve the desired effect, the two coils are connected to the line devices so that the currents flowing through the two coils run in opposite directions electrically.

TABLE 1

| | | Ø of lead | I | R* | Inner | Outer Ø | Height |
|---|---|---|---|---|---|---|---|
| Coil | Windings | (mm) | [A] | [Ω] | Ø [mm] | [mm] | [mm] |
| (1) | 1000 | 1 | 1.5 | 12.5 | 150 | 190 | 60 |
| (2) | 1500 | 1.5 | 5.0 | 14 | 260 | 320 | 130 |

*Resistance when cold.

Preferred operating parameters and limits for operating a corresponding arc source are summarized in Table 2 (target diameter approx. 160 mm, d=6-12 mm, target material: Ti or TiAl).

TABLE 2

| Parameter | Unit | Preferred range | Lower, upper limit |
|---|---|---|---|
| Pressure | mbar | 10⁻⁴-4 × 10⁻¹ | 10⁻⁴-10⁻¹ |
| Arc current | A | 150-210 | 40-250 |
| Arc voltagae | V | 20-35 | 10-100 |
| Vaporization rate | g/min | approx. 0.3 | up to approx. 0.4 |
| Substrate distance | mm | 200-300 | 100-550 |
| Coating diameter* | mm | 200 | 220 |

Table 3 also shows examples of kinds of operations depositing TiN or TiAlN, whereby a so-called bias voltage was applied to the substrate.

TABLE 3

| | Bias [V] | Ar [sccm] | N₂ [sccm] | p (mbar) |
|---|---|---|---|---|
| TiN | 100 | 400 | 800 | 3.8 10⁻² |
| TiAlN | 40-150 | 400 | 800 | 3.8 10⁻² |

The experiments were done on an RCS coating system from the Balzer Company with an octagonal cross section and approx. 1000-liter coating volume. The diameter of the coating chamber was 1070 mm, the height 830 mm.

FIG. 2 shows schematically, in an example of a circular target 6, the forces of a radially symmetrical magnetic field produced on the surface of the target being exerted on a spark. The spark is considered a moved point charge Q_{arc}.

Generally, a charged particle moved in the magnetic field is deflected by the force F=Q (v×B). Here, F is the force exerted on a charge Q moved in the magnetic field, V is the speed of the charge Q moved at right angles to the field lines and B is the magnetic induction of the field. If one considers the current flow of a spark directed basically perpendicular to the target surface, while neglecting the small influence on the applied magnetic field by the electromagnetic field of the target cathode, then the charged particle experiences, due to a force F_{∥} directed parallel to the surface and thus perpendicular to the current flow I_{arc} of a radially symmetrical magnetic field B_{∥}, an acceleration of the spark path at right angles to the field line, i.e., depending on the field direction clockwise or counter clockwise. Against it a magnetic field component B⊥₋ or B⊥₊ of the outer magnetic field perpendicular to the target surface brings about first a deflection of the charge carrier of the current flow I_{acr} coming in perpendicular, since the cross product of the vectors V×B here is zero. Only after the spark goes through a counter-clockwise deflection, shown for example in top view, due to the deflection when it hits the target surface, and also has a speed component parallel to the target surface, are the two forces F_{∥}_{_{−}} and F_{∥}_{₊} produced by the perpendicular magnetic field components B_{∥}_{_{−}} and B_{∥}_{_{÷}} now exerted. The spark is deflected toward the middle of the target, as shown, by B_{∥}_{_{−}} and, on the other hand, B_{∥}_{₊} gives the spark a speed component that moves it toward the rim of the target.

As mentioned in the consideration of the state of the art, this effect can be used by a two-coil arrangement with a time-altered current feed in order to move the spark along a radially moveable zero line of the perpendicular magnetic field component B⊥ over the target surface.

As an example of a known magnetic field made up of permanent magnets, FIG. 3 shows its parallel and perpendicular components on the surface of the target. In this arrangement of magnets, magnets with an identical pole orientation are placed on the back of the target near the rim, and one or more magnets with opposite poles stands opposite them in the center of the target. Compared to the magnetron arrangements for sputter magnetrons, the magnets arranged similarly here have a much lower field strength to achieve the desired guidance effect.

FIG. 4 shows a vectorial depiction from FIG. 3 of the force exerted on a spark I_{arc} burning perpendicularly from the plasma on the surface and deflected circularly by the parallel magnetic field at positions 1-7 of the target surface. Here, B_{∥} causes the tangentially working force F_{∥} and B⊥ a force F⊥ working radially normally, i.e., working radially in the target plane. The practical application shows that the spark path runs basically on a circular ring at a radial distance of 4-6 cm from the center of the target and from there contracts periodically in the middle of the target. This spark path is produced since at a radial distance of 5 cm, the perpendicular magnetic field is zero, and the parallel field maximal. Due to the parallel field, the spark moves in a tangential direction, as shown in FIG. 2. Since the perpendicular field at a radial distance between 4-6 cm is not very different from zero, the spark is moved neither to the middle of the target nor to the rim of it and basically runs in the area of the circular ring mentioned.

In the middle of the target, as shown in FIG. 3, the parallel component of the magnetic field, however, cuts through the zero line, while the perpendicular component runs through a maximum. A spark coming once from the path of the strong circular parallel magnetic field in the direction of the middle of the target goes through no deflection or at least only a slight deflection there, since the spark falling perpendicular is hardly acceleraged by the weak force F_{∥}, which is why the large force Fi has scarcely any effect. Therefore, the spark slows down in the central area over the surface of the target and heats it up locally so high that the target material is vaporized like an explosion, whereupon the spark goes out. This also causes a higher emission of neutral particles (spatter) and high target removal in the middle of the target. This path of the spark also proves unfavorable in practice, since only a relatively small part of the target surface is removed, which leads to the formation of erosion profiles and frequent target changes to maintain the mechanical stability of the target. Thus, only a fraction of the frequently expensive target material can be vaporized before the end of the target's lifespan.

FIG. 5 shows the path of the perpendicular B⊥ and parallel B_{∥} components of a magnetic field according to the invention, as it is produced, for example by an arc source described in FIG. 1 on the surface of the target or directly in front of it by superimposing two coil fields. Here, the coil currents in Table 1 are set constant at 1.5 A for the first coil 9 and 5 A for the second coil 10, instead better take the references (1) and (2) from FIG. 1.

The magnetic field produced in this way is characterized by a path of the perpendicular component that is constant over a wide range, unlike as in FIG. 3, and has clearly smaller values. Thus, the perpendicular component B⊥ here runs between +5 and −5 Gauss, while the perpendicular component in FIG. 3 is between +80 and −120 Gauss, with a marked minimum in the central area. Also, the parallel component B_{∥} shown in FIG. 5 is weaker overall than the one in FIG. 3. Starting from a value of approx. 20 Gaus on the rim of the target, B_{∥} runs at a gradient of roughly 4 Gauss/cm, quasi-linearly to the area near the turning point (corresponds to a minimum in polar coordinate view). Only in its direct surrounding area does the curve flatten out clearly. The formation of one or more B⊥ zero lines in connection with maximal B_{∥} values is consciously avoided by a first coil whose inner diameter corresponds roughly to the target projection, whereby the spark is not forced onto a preferred path, preventing the formation of marked removal profiles, like for example racetracks running around. Similar magnetic fields can also be produced by permanent magnets in a way that is known.

Like FIG. 4, FIG. 6 shows a vectorial view of the force exerted on a spark by an arc source according to the invention, as described in FIG. 1, in positions 1-7 on the surface of the target. This could also explain how a magnetic system designed and operated according to the invention effectively prevents the spark from contracting toward the middle of the target in a damaging way. Due to the parallel force component F_{∥} rising basically continuously to the outside, the spark has a relatively constant angle speed over the entire radial area of the target; the spark thus runs faster the farther it is from the middle of the target. At the same time, the centripetal force component F⊥ is smaller than the one in FIG. 4.

When such an arc source is operated, it can be seen that there is a fine ramification of the arc current into many small sparks, which run off the whole area of the target. The magnetic field created by superimposing the two coil fields also forms a far field, which makes the plasma bundle into a plasma jet, which can in turn be deflected by additional coils. Since with the same target capacity, removal is at least as large as for conventional arc sources, the coating rate is higher when the stream of ions is aligned in the direction of the workpiece 3. This bundling can be set to the requirements to a large extent, for example by setting the coil currents to the respective, especially geometric ratios, like for example the desired coating height, substrate target distance, etc.

FIGS. 7 and 8 show two other embodiments of the arc source in the invention, whereby in FIG. 7 the second magnet system 10 includes the first magnet system 9, while in FIG. 8 the second magnet system 10 is placed in front of the target 6. With the arc source shown in FIG. 8, the second magnet system can also have dimensions similar to the first system, especially when the first and second systems are arranged to work symmetrically toward the target, and the inner diameters chosen are equal to or greater than the outer dimensions of the target.

FIG. 9 shows a vacuum treatment system 1 with arc sources 2 that work laterally on one or more workpieces moved around the system axis 13. Other coils 14 are provided in a Helmholz arrangement for vertical deflection of the plasma beam.

FIG. 10 shows a coating system 1 with 6 arc sources 2 in cross section, in which all sources 2 are basically oriented at right angles in the direction of the system axis 13.

FIGS. 11 to 16 show the paths produced at different settings of the coil current of the B⊥ and B_{∥} components of the magnetic field on the surface of the target. The arc sources were operated according to the operating parameters described in FIG. 1 to find an optimal setting range and limits.

FIGS. 11 and 12 show various B⊥ and B_{∥} curves of the magnetic field corresponding to coil settings in which the finely distributed spark path desired can be achieved. Here it should be noted that B⊥ and B_{∥} values in a given geometric configuration cannot be set independently of one another, which is why a B⊥ distribution in FIG. 11 only corresponds to the B_{∥} distribution in FIG. 12 with the same reference.

FIGS. 13 and 14 show a borderline case in which the arc does run finely distributed, but the first signs of periodic contraction can be seen with the naked eye in the middle. If the B⊥ distribution is moved more clearly further toward positive values, there is a rougher spark path on the rim of the target.

It was also found that B⊥ distribution on both sides of the zero line allows higher differences in magnetic field strength, i.e., more non-uniform B⊥ distribution on the surface of the target, with approximately constant finely and uniformly distributed spark path than B⊥ distribution lying completely over or under the zero line.

1. A vacuum arc source including a target with a surface for operating an arc discharge, wherein the target is arranged in the effective area of a device producing a magnetic field, characterized by the fact that the device producing the magnetic field includes at least two magnet systems with opposite poles and is designed so that the component B⊥ of the resulting magnetic field perpendicular to the surface has basically constant values over a large part of the surface or is zero.

2. The arc source in claim 1, characterized by the fact that the value of the perpendicular magnetic field component B⊥ is smaller than 30, preferably smaller than 20 and very preferably smaller than 10 Gauss.

3. The arc source in one of the preceding claims, characterized by the fact that the greater part of the surface extends from the middle of the target surface to the rim, and so that the greater part includes at least 50%, especially preferred 60% or more of the geometrically determining mass or masses of the target surface.

4. The arc source in one of the preceding claims, characterized by the fact that on the rim of the target surface, the values _{B}⊥_{R} of the perpendicular magnetic field component rise, fall and/or change signs compared to the values B⊥_{M} in the middle of the target surface.

5. The arc source in one of the preceding claims, characterized by the fact that the value of the parallel magnetic field component B_{∥} is basically zero in the middle and in the direction of the rim of the target surface rises or falls, preferably symmetrically in relation to the middle of the target, especially preferred basically rises linearly.

6. The arc source in one of the preceding claims, characterized by the fact that the first of the at least two magnet systems with opposite poles includes at least one first electromagnetic coil placed behind the target.

7. The arc source in claim 6, characterized by the fact that the inner dimensions of the first coil basically coincide with a deviation from a maximum of plus/minus 30%, preferably plus/minus 20% with the projection of the outer dimensions of the surface.

8. The arc source in one of claims 1 to 5, characterized by the fact that the first of the at least two magnet systems with opposite poles is comprised of one or more permanent magnets placed behind the target.

9. The arc source in claim 8, characterized by the fact that the permanent magnet or magnets themselves have low field strength, or have a distance from the target such that the field strength on the surface of the target is low.

10. The arc source in one of the preceding claims, characterized by the fact that the second of the at least two magnet systems with opposite poles has at least one second coil arranged coaxially to the first magnet system.

11. The arc source in claim 10, characterized by the fact that the second coil is placed behind the first magnet system.

12. The arc source in claim 10, characterized by the fact that the second coil is placed at some distance in front of the target.

13. The arc source in claim 10, characterized by the fact that the second coil includes the first magnet system at least partly coaxially.

14. The arc source in one of claims 10 to 13, characterized by the fact that the second coil has a higher number of windings and/or a larger diameter than the first coil.

15. The arc source in one of the preceding claims, characterized by the fact that the target is connected as a cathode.

16. The arc source in one of the preceding claims, characterized by the fact that the target is connected as an anode.

17. A vacuum system in which at least one arc source is arranged according to one of claims 1 to 16.

18. The system in claim 17, characterized by the fact that the at least one arc source works in the direction of the axis of the system and has at least one other electromagnetic coil arranged concentrically to the axis of the system in order to deflect the plasma beam produced.

19. The system in claim 18, characterized by the fact that the at least one other coil is connected to at least one time-altered current source with a control unit, in order to deflect the alignment of the plasma beam produced by the at least one arc source variably.

20. The system in one of claims 18 to 19, characterized by the fact that at least two other electromagnetic coils, preferably in the upper and lower or corresponding areas laterally bordering the system are arranged concentrically to the axis of the system and have a different or the same diameter or a design basically corresponding to a Helmholz coil arrangement.

21. A method of operating an arc discharge on the target surface of an arc source using a device producing a magnetic field, characterized by the fact that a magnetic field is produced on the surface with the device for producing a magnetic field, whose perpendicular component B⊥ runs over a large part of the surface basically constant near or at zero.

22. The method in claim 21, characterized by the fact that the value B⊥ of the perpendicular magnetic field component is set to be smaller than 30, preferably smaller than 20 and more preferably smaller than 10 Gauss.

23. The method in one of claims 21 to 22, characterized by the fact that the magnetic field is set so that a large part of the surface with component B⊥ running basically constantly near or at zero extends from the middle of the target surface to the rim, so that the middle area includes at least 50% and especially preferred 60% or more of the geometrically determining mass or masses of the target surface.

24. The method in one of claims 21 to 23, characterized by the fact that, the values B⊥_{R} on the rim of the target surface of the perpendicular magnetic field components are set to rise, fall and/or change signs compared to the values B⊥_{M} in the middle of the target surface.

25. The method in one of claims 21 to 24, characterized by the fact that the value of the parallel magnetic field component B_{∥} is basically set at zero in the middle and in the direction of the rim of the target surface rises, preferably symmetrically in relation to the middle of the target, so that the force acting tangentially on the spark clockwise or counter-clockwise rises toward the rim of the target.

26. The method in one of claims 21 to 24, characterized by the fact that a magnetic field basically perpendicular to the surface is also produced in an area in front of the target.

27. The method in one of claims 21 to 26, characterized by the fact that the magnetic field strength is set to correspond to the target material and/or target thickness.

28. The method in one of claims 21 to 27, characterized by the fact that the device producing the magnetic field includes at least one coil placed behind the target, and a voltage source is applied to at least one coil to adjust the magnetic field, so that current flows in the first direction.

29. The method in one of claims 21 to 27, characterized by the fact that the device for producing the magnetic field has at least one magnet system made up of one or more permanent magnets placed behind the target.

30. The method in one of claims 28 to 29, characterized by the fact that at least one second coil is placed behind, in front or around the target, and to adjust the magnetic field, a voltage is applied to the second coil, so that a second magnetic field is produced that is directed opposite the magnetic field produced by the first magnet system.

31. A method of coating a workpiece, especially a tool and/or a component, using one of the methods in claims 20 to 29.

32. A method of coating a workpiece, especially a tool and/or a component using the arc source in claims 1 to 16.
